(19) United States
(12) Patent Application Publication
(10) Pub. No.: US 2008/0286884 A1
(43) Pub. Date: Nov. 20, 2008

(54) METHOD FOR IN-SITU REPAIRING PLASMA DAMAGE AND METHOD FOR FABRICATING TRANSISTOR DEVICE

(75) Inventors: Hsin-Fang Su, Hsinchu (TW); Shih-Chang Tsai, Hsinchu (TW); Chun-Hung Lee, Hsinchu (TW)

Correspondence Address: J C PATENTS, INC., 4 VENTURE, SUITE 250, IRVINE, CA, 92618, US

(73) Assignee: MACRONIX INTERNATIONAL CO., LTD., Hsinchu (TW)

(21) Appl. No.: 11/750,732

(22) Filed: May 18, 2007

(51) Int. Cl. H01L 21/336

(52) U.S. Cl. 438/4; 438/303; 257/E21.218; 257/E21.409

(57) ABSTRACT

A method for in-situ repairing plasma damage, suitable for a substrate, is provided. A component is formed on the substrate. The formation steps of the component include a main etching process containing plasma. The method involves performing a soft plasma etching process in the apparatus of the main etching process containing plasma to remove a portion of the substrate. The soft plasma etching process is less than 30% of the power used in the main etching process.

### BACKGROUND OF THE INVENTION

1. Field of the Invention

The present invention relates to a method for fabricating transistor device. More particularly, the present invention relates to a method for in-situ repairing plasma damage on substrate.

2. Description of Related Art

With the rapid development of IC industry, the integration of devices is increasingly enhanced. Under such trend, it has been a key issue of study in this field how to avoid short channel effect caused by device miniaturization and how to solve problems such as current leakage and short circuit caused by disposing devices adjacent to each other.

Generally, in order to isolate the gates of adjacent transistors, spacers are disposed at both sides of the gates. Moreover, the spacers can also be used as heavy doping masks to form a source/drain of a transistor. In the current fabrication progress, the spacer has become an essential component of each transistor.

A common method of forming a spacer is described as follows. First, a spacer material layer is deposited on a substrate with a gate already formed. Next, an anisotropic etching process is performed in a plasma etching reaction chamber. The principle of the anisotropic etching process is applying a bias to a base where the substrate is placed. The bias attracts and accelerates positive ions, and the ions then bombardment the substrate, so as to remove a portion of the spacer material layer and form a pair of spacers on the side wall of the gate. However, the plasma etching process may also cause some problems including plasma damage.

The plasma etching is characterized by using high energy particles to bombard the substrate, wherein the particles are mainly positive ions and a micro-amount of radiations such as UV lights and X-rays. When the high energy particles bombard the substrate, the substrate surface may be damaged, thus influencing the device characteristic. Therefore, the study on how to repair the substrate suffering plasma damage to minimize the impact on the performance of a transistor becomes quite important.

### SUMMARY OF THE INVENTION

The present invention is directed to provide a method for in-situ repairing plasma damage on substrate, which can be used to remove the surface of the substrate damaged by plasma bombard during the formation of spacers.

The present invention is further directed to provide a method for fabricating a transistor device, which can be used to repair the surface of a substrate damaged by plasma bombard, thereby ensuring the performance of the transistor device.

A method for in-situ repairing plasma damage, suitable for a substrate, is provided. A component is formed on the substrate. The formation steps of the component include a main etching process containing plasma. The method involves performing a soft plasma etching process in the apparatus of the main etching process to remove a portion of the substrate. The power used in the soft plasma etching process is less than 30% of the power used in the main etching process.

In the method for in-situ repairing plasma damage according to an embodiment of the present invention, the main etching process is used for forming a spacer.

In the method for in-situ repairing plasma damage according to an embodiment of the present invention, the material of the spacer includes silicon dioxide or silicon nitride, and the power used in the soft plasma etching process is, for example, about 50-150 W.

In the method for in-situ repairing plasma damage according to an embodiment of the present invention, the main etching process is used for forming a gate structure, and the power used in the soft plasma etching process is, for example, about 0-50 W.

In the method for in-situ repairing plasma damage according to an embodiment of the present invention, the gas used in the soft plasma etching process is, for example, fluoride, oxygen, and an inert gas.

In the method for in-situ repairing plasma damage according to an embodiment of the present invention, the fluoride is, for example, a fluorohydrocarbon.

In the method for in-situ repairing plasma damage according to an embodiment of the present invention, the fluorohydrocarbon is, for example, CF₄, CHF₃, CH₂F₂, or CH₃F.

In the method for in-situ repairing plasma damage according to an embodiment of the present invention, the flow rate of the fluorohydrocarbon ranges, for example, about 1-10 sccm.

In the method for in-situ repairing plasma damage according to an embodiment of the present invention, the flow rate of oxygen ranges, for example, about 30-50 sccm.

In the method for in-situ repairing plasma damage according to an embodiment of the present invention, the inert gas is, for example, argon.

In the method for in-situ repairing plasma damage according to an embodiment of the present invention, the flow rate of argon ranges, for example, about 100-200 sccm.

The present invention further provides a method for fabricating transistor device, which comprises the following steps. First, a substrate is provided. Next, a gate structure is formed on the substrate. Then, a deposition process and a main etching process containing plasma are performed to form a pair of spacers containing silicon dioxide on the side wall of the gate structure. Afterwards, a soft plasma etching process is performed in the apparatus of the etching process to remove a portion of the substrate. The power used in the soft plasma etching process is less than 30% of the power used in the main etching process. Then, a source/drain region is formed on the substrate.

In the method for fabricating transistor device according to an embodiment of the present invention, the power used in the soft plasma etching process is, for example, about 50-150 W.

In the method for fabricating transistor device according to an embodiment of the present invention, the gas used in the soft plasma etching process is, for example, fluoride, oxygen, and an inert gas.

In the method for fabricating transistor device according to an embodiment of the present invention, the fluoride is, for example, a fluorohydrocarbon.

In the method for fabricating transistor device according to an embodiment of the present invention, the fluorohydrocarbon is, for example, CF₄, CHF₃, CH₂F₂, or CH₃F.

In the method for fabricating transistor device according to an embodiment of the present invention, the flow rate of the fluorohydrocarbon ranges, for example, about 1-10 sccm.

In the method for fabricating transistor device according to an embodiment of the present invention, the flow rate of oxygen ranges, for example, about 30-50 sccm.

In the method for fabricating transistor device according to an embodiment of the present invention, the inert gas is, for example, argon.

In the method for fabricating transistor device according to an embodiment of the present invention, the flow rate of argon ranges, for example, about 100-200 sccm.

The present invention uses the soft plasma etching process to remove the damaged substrate surface after the etching process for spacers, thereby ensuring that the transistor device formed by the subsequent process has high reliability and preferred performance.

In order to make the aforementioned and other objectives, features, and advantages of the present invention comprehensible, embodiments accompanied with figures are described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A-1C are schematic sectional views of the manufacturing flow of the transistor device according to an embodiment of the present invention.

### DESCRIPTION OF EMBODIMENTS

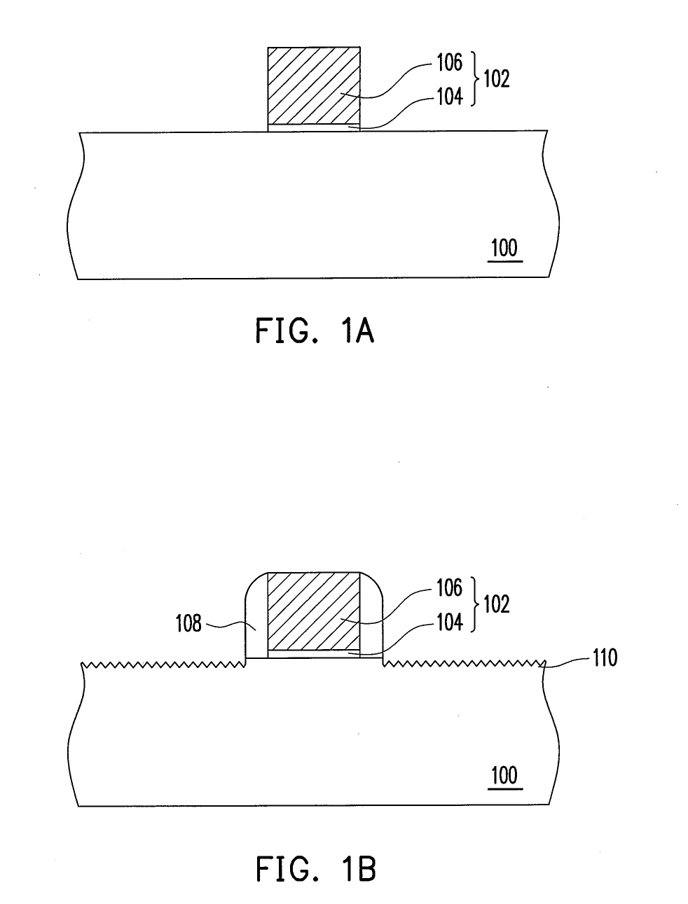

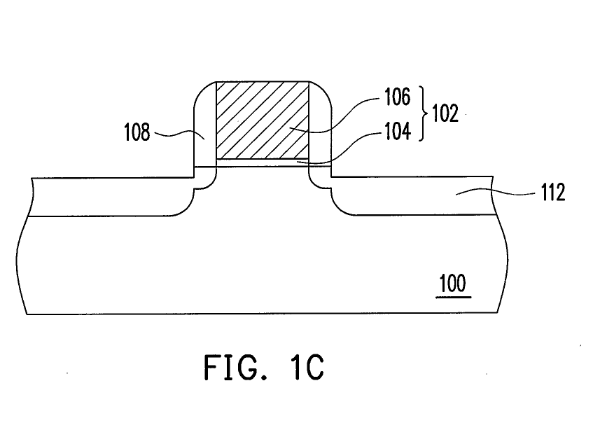

FIGS. 1A-1C are schematic sectional views of the manufacturing flow of a transistor device according to an embodiment of the present invention.

Referring to FIG. 1A, a substrate 100 is provided, which is, for example, silicon substrate or other suitable semiconductor materials. Then, a gate structure 102 is formed on the substrate 100. The gate structure 102 is composed of a gate dielectric layer 104 and a gate conductive layer 106. In an embodiment, the material of the gate dielectric layer 104 is silicon oxide or silicon nitride and the gate conductive layer 106 is, for example, composed of a polysilicon layer and a metal silicide layer. The gate structure 102 is formed by the following steps. First, an oxide material layer (not shown) is formed on the substrate 100 by, for example, thermal oxidation. Then, a polysilicon material layer (not shown) and a metal silicide material layer (not shown) are successively formed on the oxide material layer. Afterwards, a lithographic process and an etching process are performed to pattern the oxide material layer, the polysilicon material layer, and the metal silicide material layer to respectively form the gate dielectric layer 104 and the gate conductive layer 106.

Then, referring to FIG. 1B, a pair of spacers 108 is formed on the side wall of the gate structure 102. The material of the spacers 108 is, for example, silicon dioxide or silicon nitride. The spacers 108 are formed by the following steps. First, a spacer material layer (not shown) is formed on the substrate 100 by, for example, CVD. Then, a portion of the spacer material layer is removed by, for example, an anisotropic etching process that, among other things, is plasma etching process so as to form a pair of spacers 108 on the side wall of the gate structure 102. For instance, the plasma etching process includes placing the substrate 100 in a plasma etching reaction chamber (not shown) and then applying a bias on the substrate 100 to form an applied electric field in the reaction chamber. The positive ions in the plasma are driven and accelerated by the electric field perpendicular to the substrate 100 to bombard the substrate 100. Thus, a portion of the spacer material layer is removed to form the spacers 108. In an embodiment, the spacer material layer is made of silicon dioxide, and the reacting gas is a gas mixture of fluorohydrocarbon gas such as CF₄, CHF₃, CH₂F₂, or CH₃F, oxygen, and an inert gas such as Ar; the range of the power is about 600-700 W; and the pressure is about 10 mTorr.

The spacer 108 is a single-layered structure or a bi-layered structure in another embodiment. For example, the spacer 108 includes a silicon nitride spacer and a silicon oxide offset spacer between the gate structure 102 and the silicon nitride spacer.

However, the above plasma etching process also breaks atomic bonds on the surface of the substrate 100, such that a portion of the substrate surface 110 suffers physical plasma damage. Especially, when the spacer material layer is silicon dioxide, the damage to the substrate surface is severe.

Then, referring to FIG. 1C, in the apparatus of the etching process for forming the spacers 108, a portion of the substrate surface 110 suffering plasma damage is removed in-situ by, for example, a soft plasma etching process. The soft plasma etching process means that the substrate surface 110 is etched slightly. The power used in the soft plasma etching process is far small than that of the etching process for forming the spacer 108 such as a minimum effective power for generating plasma. In an embodiment, the power used in the soft plasma etching process is less than 30% of the power used in the main etching process. In an embodiment, the power used in the soft plasma etching process is about 10-20% of the power used in the main etching process. In an embodiment, the range of the power is about 50-150 W. The reacting gas used in the soft plasma etching process is a gas mixture including diluted fluoride, for example, a gas mixture of fluoride, oxygen, and an inert gas, or a gas mixture of oxygen and an inert gas. The fluoride is, for example, a fluorohydrocarbon gas, for example, CF₄, CHF₃, CH₂F₂, or CH₃F. The inert gas may be argon (Ar). The pressure of the soft plasma etching process is larger than that of the etching process for, forming the spacer 108 to decrease the directionality of the bombard species faced the substrate 100. In an embodiment, the flow rate of the fluorohydrocarbon gas ranges about 1-10 sccm; the flow rate of oxygen ranges about 30-50 sccm; the flow rate of argon ranges about 100-200 sccm; and the pressure ranges about 100-200 mTorr.

As a portion of the substrate surface 110 not covered by the gate structure 102 may be damaged by plasma bombard in the etching process for forming the spacers 108, the soft plasma etching process can be used to slightly etch and to remove the damaged substrate surface 110, thereby ensuring the performance and reliability of the transistor device formed in the subsequent process. Moreover, it should be noted that, the dry etching process and process for forming the spacers 108 are performed in the same etching reaction chamber. This design can not only reduce the process cost, but also prevent a chip from being contaminated by impurities such as dirt particles when transported among various semiconductor equipments.

Then, a source/drain region 112 is formed on the substrate 100 by, for example, an ion-implantation process. The subsequent process for forming the transistor device is known to those skilled in the art, and the details will not be described herein again.

Though the present invention has been disclosed above by using the soft plasma etching process to repair the damaged substrate surface resulting from the process for forming the spacers, they are not intended to limit the present invention. For example, the soft plasma etching process can be used to repair the damaged substrate surface resulting from the process for forming the gate structure. In an embodiment, the power used in the soft plasma etching process is less than 30% of the power used in the main etching process for forming the gate structure. In an embodiment, the power used in the soft plasma etching process is about 10-20% of the power used in the main etching process for forming the gate structure. In an embodiment, the range of the power is about 0-50 W. The reacting gas used in the soft plasma etching process is a gas mixture including diluted fluoride, for example, a gas mixture of fluoride, oxygen, and an inert gas, or a gas mixture of oxygen and an inert gas. The fluoride is, for example, a fluorohydrocarbon gas, for example, CF₄, CHF₃, CH₂F₂, or CH₃F. The inert gas may be argon (Ar). The pressure of the soft plasma etching process is larger than that of the etching process for forming the spacer 108 to decrease the directionality of the bombard species faced the substrate 100. In an embodiment, the flow rate of the fluorohydrocarbon gas ranges about 1-10 sccm; the flow rate of oxygen ranges about 30-50 sccm; the flow rate of argon ranges about 100-200 sccm; and the pressure ranges about 100-200 mTorr.

The method for fabricating transistor device according to the present invention utilizes the soft plasma etching process to repair the damaged substrate surface resulting from the process for forming the spacers or the gate structure, thereby preventing the performance of the transistor device formed in the subsequent process from being affected.

Furthermore, as the plasma etching process for repairing the substrate and the process for forming the spacers or the gate structure are successively performed in the same plasma etching reaction chamber, the process cost is saved.

Though the present invention has been disclosed above by the embodiments, they are not intended to limit the present invention. Anybody skilled in the art can make some modifications and variations without departing from the spirit and scope of the present invention. Therefore, the protecting range of the present invention falls in the appended claims.

What is claimed is:

1. A method for in-situ repairing plasma damage, suitable for a substrate, wherein a component is formed on the substrate, and the formation steps of the component include a main etching process containing plasma, the method comprising:
performing a soft plasma etching process in a apparatus of the main etching process to remove a portion of the substrate, wherein the power used in the soft plasma etching process is less than 30% of the power used in the main etching process.

2. The method for in-situ repairing plasma damage as claimed in claim 1, wherein the main etching process is used for forming a spacer.

3. The method for in-situ repairing plasma damage as claimed in claim 1, wherein the material of the spacer includes silicon dioxide or silicon nitride, and the power used in the soft plasma etching process is about 50-150 W.

4. The method for in-situ repairing plasma damage as claimed in claim 1, wherein the main etching process is used for forming a gate structure, and the power used in the soft plasma etching process is about 0-50 W.

5. The method for in-situ repairing plasma damage as claimed in claim 1, wherein the gas used in the soft plasma etching process comprises fluoride, oxygen, and an inert gas.

6. The method for in-situ repairing plasma damage as claimed in claim 5, wherein the fluoride comprises a fluorohydrocarbon.

7. The method for in-situ repairing plasma damage as claimed in claim 6, wherein the fluorohydrocarbon comprises CF₄, CHF₃, CH₂F₂, or CH₃F.

8. The method for in-situ repairing plasma damage as claimed in claim 6, wherein the flow rate of the fluorohydrocarbon ranges about 1-10 sccm.

9. The method for in-situ repairing plasma damage as claimed in claim 5, wherein the flow rate of oxygen ranges about 30-50 sccm.

10. The method for in-situ repairing plasma damage as claimed in claim 5, wherein the inert gas comprises argon.

11. The method for in-situ repairing plasma damage as claimed in claim 10, wherein the flow rate of argon ranges about 100-200 sccm.

12. A method for fabricating transistor device, comprising:
providing a substrate;
forming a gate structure on the substrate;
performing a deposition process and an etching process containing plasma to form a pair of spacers containing silicon dioxide or silicon nitride on the side wall of the gate structure;
performing a soft plasma etching process in a apparatus of the etching process to remove a portion of the substrate, wherein the power used in the soft plasma etching process is less than 30% of the power used in the main etching process; and
forming a source/drain region on the substrate.

13. The method for fabricating transistor device as claimed in claim 12, wherein the power used in the soft plasma etching process is about 50-150 W.

14. The method for fabricating transistor device as claimed in claim 12, wherein the gas used in the soft plasma etching process comprises fluoride, oxygen, and an inert gas.

15. The method for fabricating transistor device as claimed in claim 14, wherein the fluoride comprises a fluorohydrocarbon.

16. The method for fabricating transistor device as claimed in claim 15, wherein the fluorohydrocarbon comprises CF₄, CHF₃, CH₂F₂, or CH₃F.

17. The method for fabricating transistor device as claimed in claim 15, wherein the flow rate of the fluorohydrocarbon ranges about 1-10 sccm.

18. The method for fabricating transistor device as claimed in claim 14, wherein the flow rate of oxygen ranges about 30-50 sccm.

19. The method for fabricating transistor device as claimed in claim 14, wherein the inert gas comprises argon.

20. The method for fabricating transistor device as claimed in claim 19, wherein the flow rate of argon ranges about 100-200 sccm.
